(19) United States
(12) Patent Application Publication
(10) Pub. No.: US 2003/0032313 A1
(43) Pub. Date: Feb. 13, 2003

(54) Connector, terminal and terminal set

(76) Inventors: Takashi Kojima, Saitama (JP); Yasuyuki Yamamoto, Kanagawa (JP); Hiroki Iwasaki, Tokyo (JP)

Correspondence Address: KATTEN MUCHIN ZAVIS ROSENMAN, 575 MADISON AVENUE, NEW YORK, NY, 10022-2585, US

(21) Appl. No.: 09/928,906

(22) Filed: Aug. 13, 2001

(51) Int. Cl. H05K 1/00

(52) U.S. Cl. 439/79

(57) ABSTRACT

Terminals have their elastically deformable contact portions, and main body portions bent in perpendicular directions to the contact portions. The main body portions have lengths set to be effective for filtering to shut out external signals that otherwise might have invaded from electronic circuits on a main substrate, causing noises.

### BACKGROUND OF THE INVENTION

1. Field of the Invention

The present invention relates to a connector, a terminal and a terminal set, and in particular, to a connector, a terminal and a set of terminals to be less susceptive to external noises.

2. Description of the Related Art

Various electronics, such as portable telephones and personal computers, have many electronic components applied to their main substrates or wiring boards. A signal generated at an electronic circuit on the main substrate may leak to a power supply line or grounding line, invading into another electronic circuit, causing an erroneous action.

As a countermeasure to such an EMI (electromagnetic interference) or as a measure for EMC (electromagnetic compatibility), ferrite cores and the like are provided to main substrates. However, with the provision of ferrite core or the like, such a main substrate has an increased number of components and a decreased surface area for application of electronic components.

### SUMMARY OF THE INVENTION

The present invention is made with such points in view. It therefore is an object of the present invention to provide a connector, a terminal and a set of terminals adapted for filtering external signals that may cause noises, without increase in number of components nor in application area.

To achieve the object, according to an aspect of the present invention, there is provided a terminal having its elastically deformable contact portion, and main body portion. The main body portion is bent at a proximal end of the contact portion, in perpendicular direction to the contact portion. The main body portion has length set to be effective for filtering.

According to this aspect of the invention, in which the main body portion has length set to be effective for filtering, external signals that otherwise might have invaded, for example, from electronic circuits on a main substrate, causing noises, can be shut out. It therefore is possible to eliminate ferrite cores that might have increased the number of components and decreased the surface area for application.

Artisan will fully understand the above and further objects and features of the present invention by reading preferred embodiments of the invention described herein in connection with the accompanying drawings, including features recited in the appended claims, as well as explicit and implicit effects and advantages of the invention, including those to be apparent through implementation of the invention.

### BRIEF DESCRIPTION OF THE ACCOMPANYING DRAWINGS

FIG. 1 is an exploded perspective view, in schematic structure, of a connector according to an embodiment of the present invention.

FIG. 2A is a front view of the connector.

FIG. 2B is a right side view of the connector shown in FIG. 2A.

FIG. 2C is a bottom view of the connector shown in FIG. 2A.

FIG. 3 is a rear view of a connector housing of the connector having a back shell removed.

FIG. 4 is a sectional view of an essential portion of the connector.

FIG. 5 is a perspective view of IEEE connection terminals and an interposed shield plate of the connector.

### DETAILED DESCRIPTION OF THE PREFERRED EMBODIMENTS

A preferred embodiment of the present invention is described below with reference to the accompanying drawings. It is noted that like parts or elements are designated by like reference characters in the drawings, without redundant description of the parts or elements.

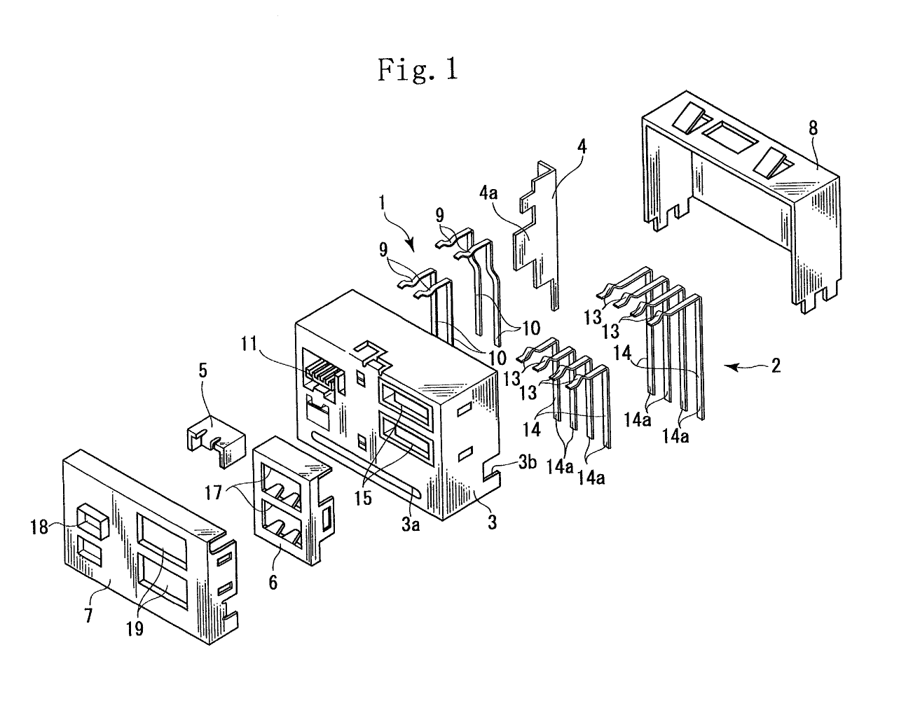

The embodiment to be described addresses a connector which has, as illustrated in FIG. 1, a housing 3 with incorporated terminals 1 in accordance with the invention. The terminals 1 have their main body portions 10 elongated for filtering to be effective so that external signals that otherwise might have invaded from electronic circuits on a main substrate, causing noises, can be shut out, allowing for elimination of ferrite cores that might have increased the number of components and decreased the surface area for application.

More specifically, as in FIG. 1, the connector in the embodiment has front and rear pairs of IEEE (institute of Electrical and Electronics Engineers) 1394 connection terminals 1, front and rear arrays of four USB (universal serial bus) connection terminals 2, and a connector housing assembly for accommodating the terminals 1 and 2. The connector housing assembly includes a box-shaped main housing 3 as a central housing member, a shield plate 4 as a rear shielding piece for the IEEE terminals 1, a first shield member 5 as a front shielding piece for the IEEE terminals 1, a second shield member 6 as a front shielding piece for the USB terminals 2, and front and rear shells 7 and 8 as front and rear housing members to be fastened to the main housing 3 to constitute an enclosure.

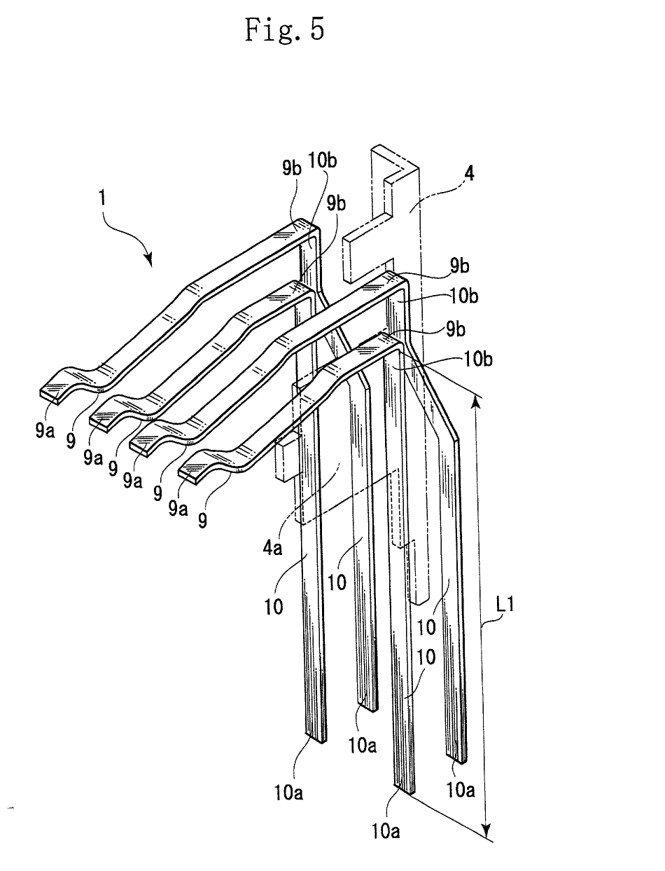

As detailed in FIG. 5, each IEEE terminal 1 is constituted with an elastically or resiliently deformable contact portion 9, and a main body portion 10 as a stem bent substantially in a perpendicular direction to the contact portion 9. The IEEE terminal 1 is integrally formed by bending a resilient metallic plate, such as of a phosphor bronze, substantially into an L shape. In order for sufficient contact to be secured on a mating contact (not shown), the contact portion 9 is configured near its distal end 9a substantially in a V shape, to be elastically or resiliently deformable, to be displaceable. The substantially V-shaped displaceable part of the contact portion 9 is brought into contact with the mating terminal. The distal end 9a of the contact portion 9 is oriented upward, in opposition to the main body portion 10 extending downward, so that the mating terminal, as it is inserted into the housing 3, can smoothly contact the substantially V-shaped part.

The main body portion 10, which has its distal end 10a and proximal end 10b, extends downward from a proximal end 9b of the contact portion 9, substantially perpendicularly to the contact portion 9. The distal end 10a of the main body portion 10 may, for example, be inserted to be soldered in a through hole or the like provided in the main substrate (or wiring board). In this embodiment, the main body portion 10 has a length L1 set to be effective for a required filtering. In other words, the length L1 between the proximal end 10b and the distal end 10a of the main body portion 10 is set to a dimension within such a range that can shut out external signals which otherwise might have invaded from electronic circuitry on the main substrate, causing noises. It is noted that if the length L1 between the proximal end 10b and the distal end 10a of the main body portion 10 exceeded the range of dimension to be effective for the filtering, this filtering might have been made ineffective due to increased impedance. In this embodiment, the length L1 of the main body portion 10 is set to 16 mm for example.

Like this, by setting the above-noted length L1 of the main body portion 10 within the range to be effective for filtering, there is eliminated the need for provision such as of a ferrite core to be used as an anti-noise countermeasure on the main substrate, with a resultant reduction expectable in number of component parts. Further, because of the unnecessity of provision such as of a ferrite core, a sufficient surface area can be secured for component application on the main substrate.

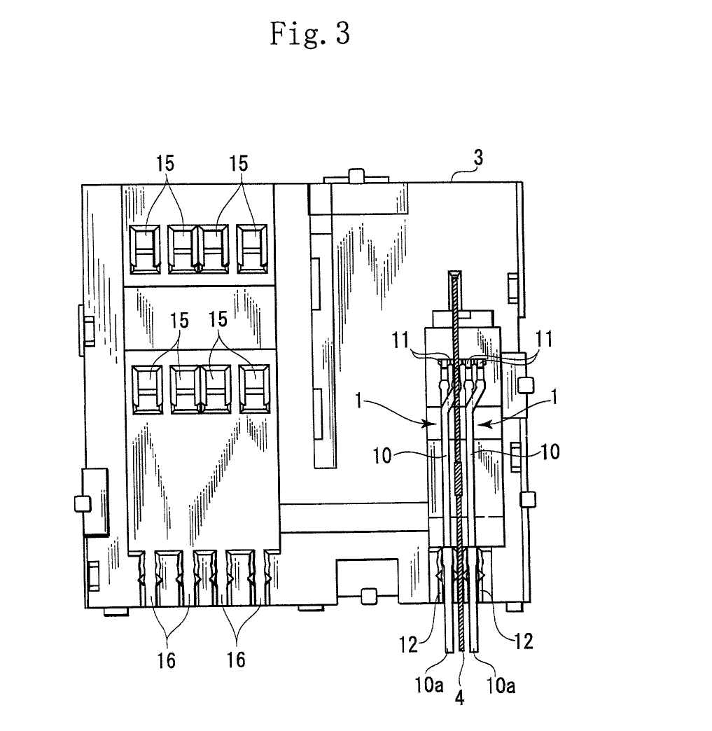

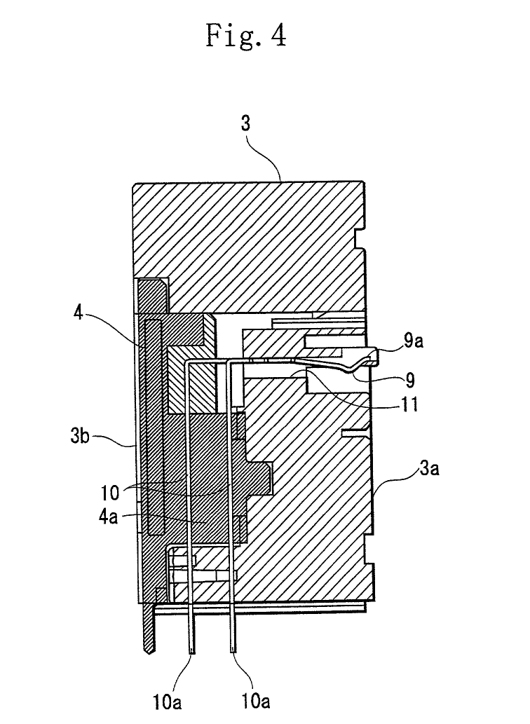

As shown in FIG. 1 as well as in FIG. 5, the IEEE terminals 1 are four in total, arranged two on one side and two on opposite side of the shield plate 4, to be accommodated all in a terminal accommodation chamber 11 of the housing 3, as shown in FIG. 3 and FIG. 4. To the terminal accommodation chamber 11 are accommodated the contact portions 9 of the IEEE terminals 1. In a defined space within the terminal accommodation chamber 11 are inserted mating terminals, whereby the elastically deformable contact portions 9 are displaced, as necessary. The main body portions 10 are fitted near distal ends thereof in stem holding grooves 12 provided in the housing 3, to be thereby fixed to the housing 3.

As shown in FIG. 1, USB terminals 2 in each array are four in total, aligned at specified intervals. In this embodiment, two sets of four USB terminals 2 are provided. As illustrated in FIG. 1, each USB terminal 2 is constituted with an elastically or resiliently deformable contact portion 13, and a main body portion 14 as a stem bent substantially perpendicularly to the contact portion 13. Like the IEEE terminal 1, the USB terminal 2 is integrally formed by bending a resilient metallic plate, such as of a phosphor bronze, substantially into an L shape.

In order for sufficient contact to be secured on a mating contact (not shown), the contact portion 13 is configured near its distal end substantially in a V shape, to be elastically or resiliently deformable, to be displaceable. The substantially V-shaped displaceable part of the contact portion 13 is brought into contact with the mating terminal. Unlike the IEEE terminal 1, the contact portion 13 of the USB terminal 2 is configured in an upwardly projecting V shape. The main body portion 14 extends downward from a proximal end of the contact portion 13, substantially perpendicularly to the contact portion 13. A distal end 14a of the main body portion 14 may, for example, be inserted to be soldered in a through hole or the like provided in the main substrate (or wiring board).

The USB terminals 2 are accommodated in two terminal accommodation chambers 15 of the housing 3 shown in FIG. 3. To the terminal accommodation chambers 15 are accommodated the contact portions 13 of the USB terminals 2. In defined spaces within the terminal accommodation chambers 15 are inserted mating terminals, whereby the elastically deformable contact portions 13 are displaced, as necessary. The main body portions 14 are fitted near distal ends thereof in stem holding grooves 16 provided in the housing 3, to be thereby fixed to the housing 3.

The housing 3 is configured as a rectangular housing member for accommodating the IEEE terminals 1 and the USB terminals 2. As described, this housing 3 is provided with the terminal accommodation chamber 11 and stem holding grooves 12 for accommodation of the IEEE terminals 1, and with the terminal accommodation chambers 15 and stem holding grooves 16 for accommodation of the USB terminals 2. As shown in FIG. 1, the terminal accommodation chambers 11 and 15 are provided through the housing 3, between a front side 3a and a rear side 3b of the housing 3. As shown in FIG. 3, the stem holding grooves 12 and 16 are provided at the rear side 3b of the housing 3.

As shown in FIG. 4 and FIG. 5, the shield plate 4 is fixed to the housing 3, so that the four IEEE terminals 1 are disposed two and two on both sides of the shield plate 4, that is, two on one side and two on opposite side. In other words, two of the four IEEE terminals 1 are separated or isolated from the remaining two IEEE terminals 1 by the shield plate 4. The shield plate 4 has a partition piece 4a as a partitioner between respective main body portions 10 of the two and two IEEE terminals 1 disposed on the above-noted both sides. This partition piece 4a prevents interferences between the IEEE terminals 1 disposed on the both sides, thus functioning for a so-called isolation control therebetween.

As shown in FIG. 1, the first shield member 5 is fixed to the housing 3, covering distal ends 9a of the contact portions 9 of the IEEE terminals 1. This first shield member 5 serves for preventing noise generating signals from invading from outside of the connector into the IEEE terminals 1. The first shield member 5 is mounted to the front side 3a of the housing 3.

As shown in FIG. 1, the second shield member 6 is fixed to the housing 3, covering distal ends of the contact portions 13 of the USB terminals 2, in a similar manner to the first shield member 5. This second shield member 6 serves for preventing noise generating signals from invading from outside of the connector into the USB terminals 2. The second shield member 6 has two open windows 17 in correspondence to the two terminal accommodation chambers 15, and is mounted to the front side 3a of the housing 3.

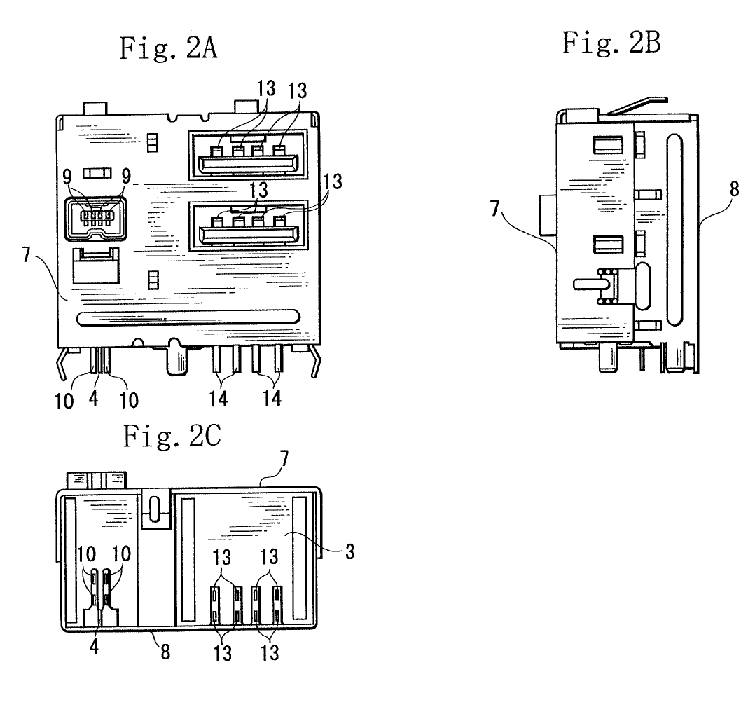

As shown in FIG. 1, FIG. 2A and FIG. 2B, the front shell 7 is fixed to the housing 3, covering the front side 3a of the housing 3. This front shell 7 is formed with open holes 18 and 19 for exposing outside the terminal accommodation chambers 11 and 15 provided in the housing 3. The front shell 7 is integrally formed by bending a metallic plate made, for example, of a phosphor bronze.

As shown in FIG. 1, FIG. 2B and FIG. 2C, the back shell 8 is fixed to the housing 3, covering the rear side 3b of the housing 3. This back shell 8 is mounted to the rear side 3b of the housing 3, to be cooperative with the front shell 7 to cover an entire outer surface of the housing 3, excepting a bottom side.

Like this, the IEEE terminals 1 and the USB terminals 2 are provided as two types of terminals different in function, in a common housing 3. However, because the lengths L1 of the main body portions 10 of the IEEE terminals 1 are set to a dimension within the range to be effective for filtering, signals generated for example from the USB terminals 2 are filtered by the IEEE terminals 1, and prevented from invading the IEEE terminals 1. Therefore, noise generating external signals invading from electronic circuitry on the main substrate to which the connector is mounted can be effectively shut out.

In the above embodiment, description is made of exemplary two types of terminals, IEEE1394 connection terminals 1 and USB connection terminals 2, which may preferably be other types of terminals.

While preferred embodiments of the present invention have been described using specific terms, such description is for illustrative purposes, and it is to be understood that changes and variations may be made without departing from the spirit or scope of the following claims.

What is claimed is:

1. A terminal comprising:
an elastically deformable contact portion having proximal end and distal end thereof; and
a main body portion extending from the proximal end substantially perpendicularly to the contact portion, the main body portion having effective length for filtering.

2. A connector comprising:
a housing;
a set of four terminals provided to the housing, the four terminals including elastically deformable contact portions, and
main body portions having effective lengths for filtering; and a shield plate fixed to the housing, for separating two of the four terminals from the remaining two terminals.

3. The connector as claimed in claim 2, further comprising:
a first shield member covering distal ends of the contact portions;
a front shell covering a front side of the housing; and
a back shell covering a back side of the housing.

4. The connector as claimed in claim 2, further comprising:
a set of USB connection terminals provided to the housing,
the USB connection terminals having elastic contact portions at distal ends thereof; and
a second shield member covering the distal ends of the USB connection terminals.

5. The connector as claimed in claim 2, wherein the four terminals comprise IEEE1394 connection terminals.

6. The connector as claimed in claim 4, wherein the four terminals comprise IEEE1394 connection terminals.

7. A set of terminals comprising:
elastically deformable contact portions having proximal ends and distal ends thereof; and
main body portions extending from the proximal ends substantially perpendicularly to the contact portions, the main body portions having effective lengths for filtering.
